(19) United States
(12) Patent Application Publication
(10) Pub. No.: US 2013/0105899 A1
(43) Pub. Date: May 2, 2013

(54) INPUT/OUTPUT ELECTROSTATIC DISCHARGE DEVICE WITH REDUCED JUNCTION BREAKDOWN VOLTAGE

(71) Applicant: MEDIATEK INC., Hsin-Chu (TW)

(72) Inventors: Tung-Hsing Lee, New Taipei City (TW); I-Cheng Lin, Hsinchu City (TW); Wei-Li Tsao, Hsinchu County (TW)

(73) Assignee: MEDIATEK INC., Hsin-Chu (TW)

(21) Appl. No.: 13/719,249

(22) Filed: Dec. 19, 2012

Related U.S. Application Data
(63) Continuation-in-part of application No. 12/541,967, filed on Aug. 16, 2009.

(51) Int. Cl. H01L 29/78

(52) U.S. Cl. CPC H01L 29/78
USPC 257/355

(57) ABSTRACT

An I/O electrostatic discharge (ESD) device having a gate electrode over a substrate, a gate dielectric layer between the gate electrode and the substrate, a pair of sidewall spacers respectively disposed on two opposite sidewalls of the gate electrode, a first lightly doped drain (LDD) region disposed under one of the sidewall spacers, a source region disposed next to the first LDD region, a second LDD region disposed under the other sidewall spacer, and a drain region disposed next to the second LDD region. The I/O ESD device has an asymmetric LDD configuration. In one embodiment, a junction of the second LDD region is shallower than that of the first LDD region.

### CROSS REFERENCE TO RELATED APPLICATIONS

This is a continuation-in-part of U.S. application Ser. No. 12/541,967 Filed Aug. 16, 2009.

### BACKGROUND OF THE INVENTION

1. Field of the Invention

The present invention relates generally to integrated circuits (ICs) and, more particularly to an input/output (I/O) electrostatic discharge (ESD) device with lower junction breakdown voltage and better ESD protection performance.

2. Description of the Prior Art

An IC chip electrically communicates with off-chip electronics to exchange information. The IC chip may employ different voltages than are employed by off-chip electronics. Accordingly, the interface between the IC chip and off-chip electronics must accommodate the voltage differences. One such interface includes a mixed voltage I/O driver.

A conventional ESD protection structure includes two NMOS transistors in a cascode configuration, where the two NMOS transistors are merged into the same active area of a substrate. For example, the two NMOS transistors allow a 5V signal to be dropped to 3.3V during normal operation while providing a parasitic lateral NPN bipolar transistor during electrostatic discharge. Under ESD conditions, the stacked transistors operate in snapback with the bipolar effect occurring between the source of the bottom NMOS transistor and drain of the top NMOS transistor.

While this I/O driver has been used for some generic designs, it has been a continuing challenge to balance ESD protection performance and I/O performance. Accordingly, it is desired to improve upon the performance of a cascode MOS driver and the ESD protection performance of the ESD device. More specifically, there is a need to remove the ESD design constraints from drivers to achieve maximum I/O performance.

### SUMMARY OF THE INVENTION

Upon reading and understanding the present disclosure it is recognized that the inventive subject matter described herein provides novel structures and methods and may include novel structures and methods not expressed in this summary. The following summary is provided to give the reader a brief summary which is not intended to be exhaustive or limiting and the scope of the invention is provided by the attached claims and the equivalents thereof.

From one aspect of this invention, an I/O electrostatic discharge (ESD) device comprises a gate electrode over a substrate; a gate dielectric layer between the gate electrode and the substrate; a pair of sidewall spacers respectively disposed on two opposite sidewalls of the gate electrode; a first lightly doped drain (LDD) region disposed under one of the sidewall spacers; a source region disposed next to the first LDD region; a second LDD region disposed under the other sidewall spacer; and a drain region disposed next to the second LDD region. A doping concentration of the second LDD region is larger than a doping concentration of the first LDD region.

From another aspect of this invention, an I/O ESD device comprises a first MOS transistor having a gate electrode, a source structure and a drain structure; and a second MOS transistor serially connected to the first MOS transistor by sharing the source structure of the first MOS transistor. The source structure of the first MOS comprises a first LDD region, the drain structure of the first MOS comprises a second LDD region, and a doping concentration of the second LDD region is larger than a doping concentration of the first LDD region.

From still another aspect of this invention, an I/O ESD device includes a gate electrode over a substrate; a gate dielectric layer between the gate electrode and the substrate; a pair of sidewall spacers respectively disposed on two opposite sidewalls of the gate electrode; a first LDD region disposed under one of the sidewall spacers; a source region disposed next to the first LDD region; a second LDD region disposed under the other sidewall spacer; and a drain region disposed next to the second LDD region; wherein a junction of the second LDD region is shallower than that of the first LDD region.

From still another aspect of this invention, an I/O ESD device includes a gate electrode over a substrate; a gate dielectric layer between the gate electrode and the substrate; a pair of sidewall spacers respectively disposed on two opposite sidewalls of the gate electrode; a first LDD region disposed under one of the sidewall spacers; a source region disposed next to the first LDD region; a second LDD region disposed under the other sidewall spacer; and a drain region disposed next to the second LDD region; wherein a junction of the second LDD region is substantially equal to that of the first LDD region, and a doping concentration of the second LDD region is greater than a doping concentration of the first LDD region.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic, cross-sectional view of an ESD device according to one embodiment of this invention.

FIG. 2 is a schematic, cross-sectional view of a cascode I/O ESD device according to another embodiment of this invention.

FIG. 3 shows a cross-sectional view of an ESD device according to yet another embodiment of this invention.

FIG. 4 shows a cross-sectional view of an ESD device according to yet another embodiment of this invention.

FIG. 5 shows a cross-sectional view of an ESD device with asymmetric LDD configuration according to still another embodiment of this invention.

FIG. 6 shows a cross-sectional view of an ESD device according to still another embodiment of this invention.

### DETAILED DESCRIPTION

In the following detailed description of the invention, reference is made to the accompanying drawings which form a part hereof, and in which is shown, by way of illustration, specific embodiments in which the invention may be practiced. These embodiments are described in sufficient detail to enable those skilled in the art to practice the invention. Other embodiments may be utilized and structural, logical, and electrical changes may be made without departing from the scope of the present invention. The following detailed description is, therefore, not to be taken in a limiting sense, and the scope of the present invention is defined only by the appended claims, along with the full scope of equivalents to which such claims are entitled. In the following description and in the claims, the terms “include” and “comprise” are used in an open-ended fashion, and thus should be interpreted to mean “include, but not limited to . . . ”. Also, the term “couple” is intended to mean either an indirect or direct electrical connection. Accordingly, if one device is coupled to another device, that connection may be through a direct electrical connection, or through an indirect electrical connection via other devices and connections.

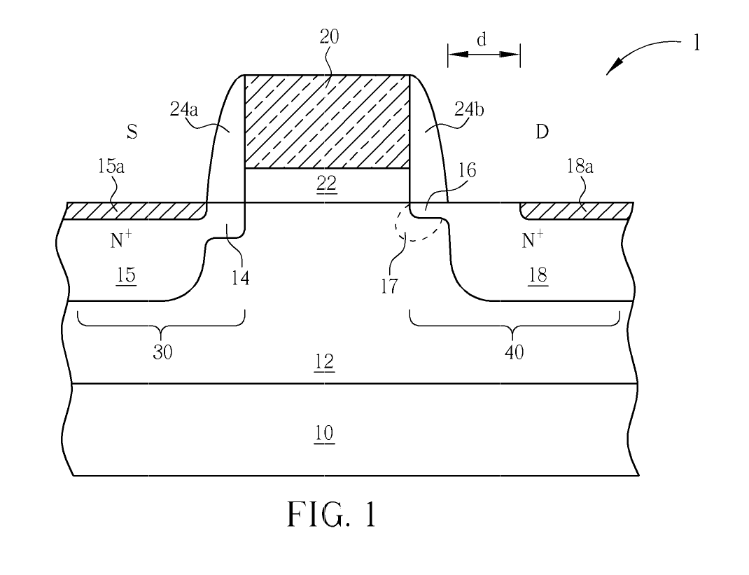

FIG. 1 shows a cross-sectional view of an ESD device 1 according to one embodiment of this invention. As shown in FIG. 1, the ESD device 1 could be formed in an I/O P well 12 that is provided in a semiconductor substrate 10 such as a P type silicon substrate. According to this embodiment, the ESD device 1 is an NMOS transistor and is fabricated in an I/O device region. However, it is to be understood that this invention could be applicable to PMOS transistors. The ESD device 1 comprises a gate electrode 20 provided over a region of the I/O P well 12. The gate electrode 20 could be a stack structure comprising, for example, a conductor such as a polysilicon layer, metal or metal silicide, and insulator such as a silicon nitride capping the conductor. It is understood that the gate electrode 20 could be any suitable gate structure commonly used in the I/O devices.

A gate dielectric layer 22 could be provided between the gate electrode 20 and the I/O P well 12. The gate dielectric layer 22 could be formed by a gate dielectric layer for an I/O device. The gate dielectric layer 22 could be formed concurrently with the I/O devices and thus has a thicker thickness than that of the core devices. For example, the gate dielectric layer 22 could have a thickness of about 35-70 angstroms, while the core devices (not shown) could have a thickness of about 10-25 angstroms, based on a 65 nm technology node. A sidewall spacer 24a and a sidewall spacer 24b could be formed on two opposite sidewalls of the gate electrode 20. The sidewall spacers 24a and 24b could comprise dielectric materials such as silicon oxide, silicon nitride, silicon oxynitride or a combination thereof. It is to be understood that the sidewall spacers 24a and 24b could further comprise a liner such as an oxide liner in one embodiment.

On the left-hand side of the gate electrode 20, a source structure 30 is provided in the I/O P well 12. The source structure 30 could include a first NLDD (N-type lightly doped drain) region 14 that is disposed under the sidewall spacer 24a, a N+ source region 15 disposed next to the first LDD region 14, and a salicide layer 15a on the N+ source region 15. The first NLDD region 14 could be an I/O NLDD region formed by an LDD implantation process for an I/O device.

For example, in accordance with one embodiment, the first NLDD region 14 could be formed by implanting N type dopants, such as phosphorus and arsenic, with a dosage of, for example, about 2×10¹³−8×10¹³ atoms/cm², and the first NLDD region 14 could have a junction depth of about 300-1,000 angstroms. In one embodiment, the N+ source region 15 could be formed after the formation of the sidewall spacer 24a and 24b. The N+ source region 15 could be formed by implanting N type dopants, such as arsenic, with a dosage of, for example, about 1×10¹⁵−5×10¹⁵ atoms/cm², into the I/O P well 12. For example, in accordance with the embodiment, the N+ source region 15 could have a junction depth of about 800-1,500 angstroms. The salicide layer 15a, which could be cobalt salicide or nickel salicide for example, could be formed next to the edge of the sidewall spacer 24a and does not extend over the first NLDD region 14.

On the right-hand side of the gate electrode 20, a drain structure 40 is provided in the I/O P well 12 and is opposite to the source structure 30. The drain structure 40 could include a second NLDD region 16 that is disposed under the sidewall spacer 24b, a P type pocket region 17 around the second NLDD region 16, a N+ drain region 18 disposed next to the second LDD region 16, and a salicide layer 18a on the N+ drain region 18. The N+ drain region 18 could be coupled to an I/O pad. The second NLDD region 16 could be a core LDD region formed by an LDD implantation process for a core device. It is one feature of this embodiment of the present invention that the ESD device 1 has an asymmetric LDD configuration. A doping concentration of the second LDD region 16 is larger than a doping concentration of the first LDD region 14. To have the asymmetric LDD configuration, in this embodiment, the ESD device 1 does not include an I/O NLDD or any extra ESD implant in its drain structure 40, but instead, incorporates the second NLDD 16 and the halo implant (P type pocket region 17). By incorporating the second NLDD 16 and the P type pocket region 17 and by eliminating the I/O NLDD from the drain structure 40, the junction breakdown voltage of the ESD device 1 can be reduced and better ESD performance can be obtained.

The second NLDD region 16 could be formed concurrently with the core NLDD implant of the core devices. In accordance with one embodiment, the second NLDD 16 could be formed by implanting N type dopants, such as arsenic, with a dosage of, for example, about 5×10¹⁴−3×10¹⁵ atoms/cm², and the second NLDD region 16 could have a junction depth of about 200-900 angstroms. The P type pocket region 17 could be formed by a halo implantation performed in the fabrication process for core devices. In accordance with one embodiment, the P type pocket region 17 could be formed by implanting P type dopants, such as In or B or BF₂, with a dosage of, for example, about 1×10¹³−9×10¹³ atoms/cm², and the P type pocket region 17 could have a junction depth of about 200-900 angstroms. The salicide layer 18a, which could be cobalt salicide or nickel salicide for example, could be formed with an offset d away from the edge of the sidewall spacer 24b to prevent leakage. However, in another embodiment, there could not be an offset between the salicide layer 18a and the edge of the sidewall spacer 24b. It is to be understood that this invention could be applicable to PMOS transistors as well, for example, the LDD region 14, source region 15, etc. could respectively be a PLDD region, a P+ source region, etc. instead.

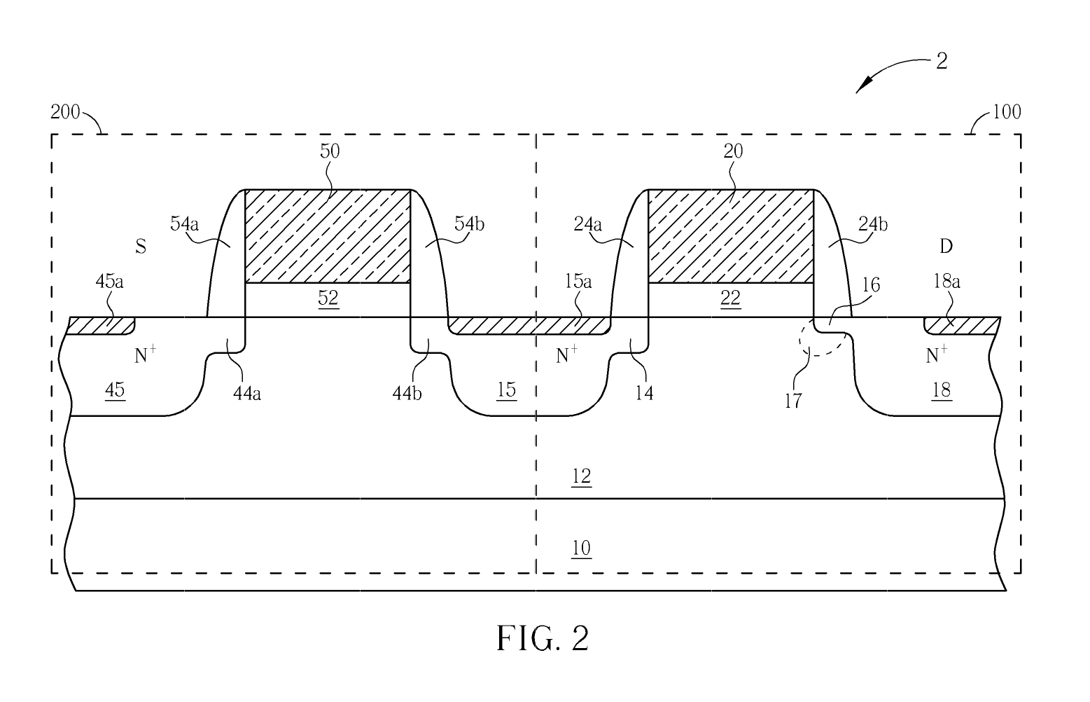

FIG. 2 is a schematic, cross-sectional view of a cascode I/O ESD device 2 according to another embodiment of this invention. As shown in FIG. 2, the cascode I/O ESD device 2 could comprise two NMOS transistors 100 and 200 in cascode configuration, wherein the NMOS transistor 100 could have a similar structure to that of the ESD device 1 as depicted in FIG. 1. The NMOS transistor 100 could include a gate electrode 20 provided over a region of the I/O P well 12. A gate dielectric layer 22 could be provided between the gate electrode 20 and the I/O P well 12. The gate dielectric layer 22 could be formed by a gate dielectric layer for an I/O device. A sidewall spacer 24a and a sidewall spacer 24b could be formed on two opposite sidewalls of the gate electrode 20. The sidewall spacers 24a and 24b could comprise dielectric materials such as silicon oxide, silicon nitride, silicon oxynitride or a combination thereof. On the left-hand side of the gate electrode 20, a source structure is provided in the I/O P well 12. The source structure could include a first NLDD region 14 situated under the sidewall spacer 24a, an N+ source region 15 disposed next to the first NLDD region 14, and a salicide layer 15a. The first NLDD region 14 could be an I/O NLDD region formed by an LDD implantation process for an I/O device. For example, in accordance with one embodiment, the first NLDD region 14 could be formed by implanting N type dopants, such as phosphorus and arsenic, with a dosage of, for example, about 2×10¹³−8×10¹³ atoms/cm², and the first NLDD region 14 could have a junction depth of about 300-1,000 angstroms. In one embodiment, the N+ source region 15 could be formed after the formation of the sidewall spacer 24a and 24b. The N+ source region 15 could be formed by implanting N type dopants, such as arsenic with a dosage of, for example, about 1×10¹⁵−5×10¹⁵ atoms/cm², into the I/O P well 12. For example, in accordance with the embodiment, the N+ source region 15 could have a junction depth of about 800-1,500 angstroms. The salicide layer 15a, which could be cobalt salicide or nickel salicide for example, could be formed next to the edge of the sidewall spacer 24a and does not extend over the first NLDD region 14.

On the right-hand side of the gate electrode 20, a drain structure, which could be coupled to an I/O pad, is provided in the I/O P well 12. The drain structure could include a second NLDD region 16 that is situated under the sidewall spacer 24b, a P type pocket region 17 around the second NLDD region 16, a N+ drain region 18 disposed next to the second LDD region 16, and a salicide layer 18a. The second NLDD region 16 could be a core LDD region formed by an LDD implantation process for a core device. The NMOS transistor 100 does not include an I/O NLDD or any extra ESD implant in its drain structure. The NMOS transistor 100 has an asymmetric LDD configuration. A doping concentration of the second LDD region 16 is larger than a doping concentration of the first LDD region 14. By incorporating the second NLDD 16 and the P type pocket region 17 and by eliminating the I/O NLDD from the drain structure, the junction breakdown voltage of the ESD device can be reduced and better ESD performance can be obtained.

The second NLDD region 16 could be formed concurrently with the core NLDD implant of the core devices. In accordance with one embodiment, the second NLDD 16 could be formed by implanting N type dopants, such as arsenic, with a dosage of, for example, about 5×10¹⁴−3×10¹⁵ atoms/cm², and the second NLDD region 16 could have a junction depth of about 200-900 angstroms. The P type pocket region 17 could be formed by a halo implantation performed in the fabrication process for core devices. In accordance with one embodiment, the P type pocket region 17 could be formed by implanting P type dopants, such as In or B or BF₂, with a dosage of, for example, about 1×10¹³−9×10¹³ atoms/cm², and the P type pocket region 17 could have a junction depth of about 200-900 angstroms. The salicide layer 18a, which could be cobalt salicide or nickel salicide for example, could be formed with an offset d away from the edge of the sidewall spacer 24b to prevent leakage.

The NMOS transistor 200 is serially connected to the NMOS transistor 100 by sharing the N+ source region 15 that could also function as a drain of the NMOS transistor 200. Unlike the NMOS transistor 100, which is an asymmetric NMOS transistor structure having such as an I/O NLDD at its source side and a core NLDD/pocket at its drain side, the NMOS transistor 200 is a symmetric NMOS transistor structure having such as an I/O NLDD at each of its source and drain sides. As shown in FIG. 2, the NMOS transistor 200 comprises a gate electrode 50 provided on a region of the I/O P well 12 and is adjacent to the gate electrode 20. A gate dielectric layer 52 could be provided between the gate electrode 50 and the I/O P well 12. The gate dielectric layer 52 could be formed by a gate dielectric layer for an I/O device. A sidewall spacer 54a and a sidewall spacer 54b could be formed on two opposite sidewalls of the gate electrode 50. The sidewall spacers 54a and 54b could comprise dielectric materials such as silicon oxide, silicon nitride, silicon oxynitride or a combination thereof. On the left-hand side of the gate electrode 50, a source, which could be connected to VSS or ground, is provided in the I/O P well 12. An I/O NLDD 44a could be provided under the sidewall spacer 54a and an I/O NLDD 44b could be provided under the sidewall spacer 54b such that the NMOS transistor 200 has a symmetric LDD configuration. Merging with the I/O NLDD 44a, an N+ drain region 45, which could be formed concurrently with the N+ regions 15 and 18, could be provided next to the sidewall spacer 54a. The N+ source region 45 could be formed after the formation of the sidewall spacer 44a and 44b. The N+ source region 45 could be formed by implanting N type dopants, such as arsenic, with a dosage of, for example, about 1×10¹⁵−5×10¹⁵ atoms/cm², into the I/O P well 12. For example, in accordance with one embodiment, the N+ source region 45 could have a junction depth of about 800-1,500 angstroms.

It is to be understood that this invention could be applicable to PMOS transistors as well, for example, the LDD region 14, source region 45, etc. could respectively be a PLDD region, a P+ source region, etc. instead.

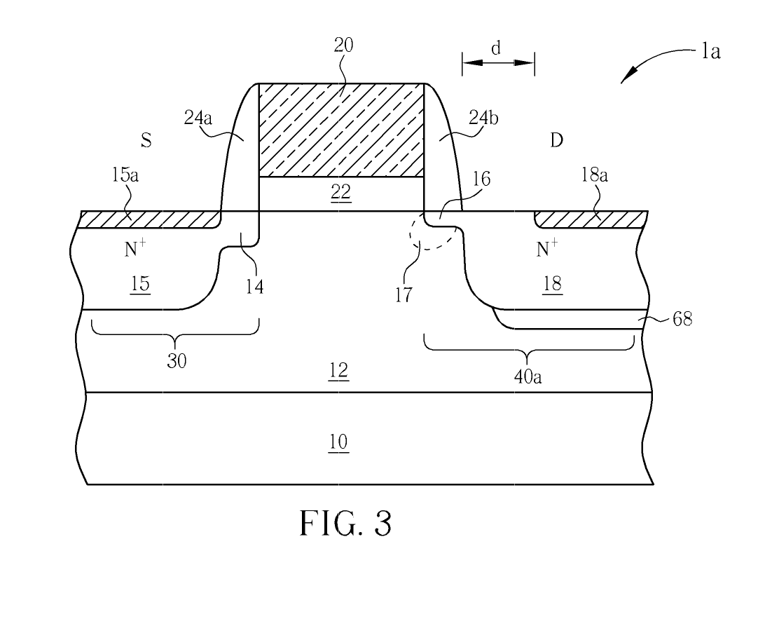

FIG. 3 shows a cross-sectional view of an ESD device la according to yet another embodiment of this invention. It is understood that the NMOS transistor 100 of FIG. 2 can be replaced with the ESD device 1a according to another embodiment of this invention. As shown in FIG. 3, the ESD device 1a could have a similar structure to that of the ESD device 1 as depicted in FIG. 1, however, the drain structure 40a is different. On the right-hand side of the gate electrode 20, a drain structure 40a is provided in the I/O P well 12 and is opposite to the source structure 30. The drain structure 40a could include a second NLDD region 16 that is situated under the sidewall spacer 24b, a P type pocket region 17 around the second NLDD region 16, a N+ drain region 18, an ESD implant region 68 under the N+ drain region 18, and a salicide layer 18a on the N+ drain region 18. The ESD device 1a also has an asymmetric LDD configuration. A doping concentration of the second LDD region 16 is larger than a doping concentration of the first LDD region 14. By incorporating the second NLDD 16 and the P type pocket region 17 and by eliminating the I/O NLDD from the drain structure 40a, the junction breakdown voltage of the ESD device can be reduced and better ESD performance can be obtained. The difference between the ESD device 1 of FIG. 1 and the ESD device 1a of FIG. 3 is that the ESD device 1a of FIG. 3 incorporates an extra ESD implant region 68 in its drain structure 40a. According to one embodiment, the ESD implant region 68 is a P type doped region. It is to be understood that this invention could be applicable to PMOS transistors as well, for example, the ESD implant region 68 could be an N type doped region instead.

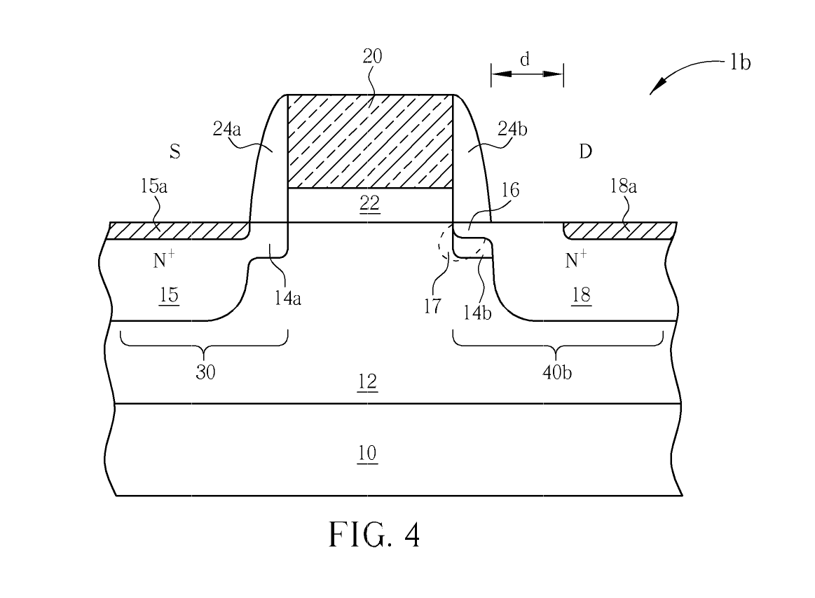

FIG. 4 shows a cross-sectional view of an ESD device 1b according to yet another embodiment of this invention. It is understood that the NMOS transistor 100 of FIG. 2 can be replaced with the ESD device 1b according to another embodiment of this invention. As shown in FIG. 4, the ESD device 1b could have a similar structure to that of the ESD device 1 as depicted in FIG. 1, however, the drain structure 40b is different. On the right-hand side of the gate electrode 20, a drain structure 40b is provided in the I/O P well 12 and is opposite to the source structure 30. The drain structure 40b could include an I/O NLDD region 14b, a core NLDD region 16 situated under the sidewall spacer 24b, a P type pocket region 17 around the core NLDD region 16, an N+ drain region 18, and a salicide layer 18a on the N+ drain region 18. The I/O NLDD regions 14a and 14b could be formed simultaneously and thus could have substantially the same doping concentrations. The I/O NLDD region 14b could substantially encompass the core NLDD region 16. The ESD device 1b has an asymmetric LDD configuration. A doping concentration of the second LDD region 16 is larger than a doping concentration of the first LDD region 14a. By incorporating the second NLDD 16 and the P type pocket region 17 into the drain structure 40b, the junction breakdown voltage of the ESD device 1b can be reduced and better ESD performance can be obtained. It is to be understood that this invention could be applicable to PMOS transistors as well, for example, the LDD region 14a, source region 15, etc. could respectively be a PLDD region, a P+ source region, etc. instead.

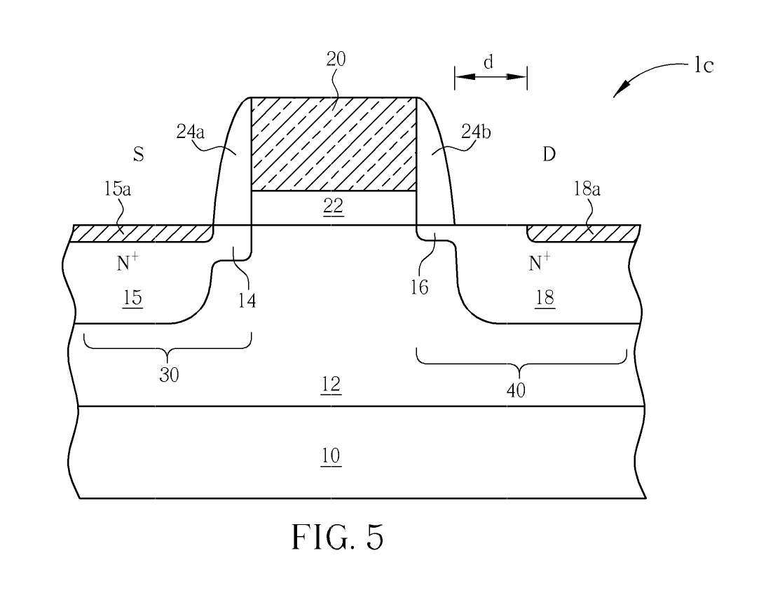

FIG. 5 shows a cross-sectional view of an ESD device 1c according to still another embodiment of this invention. As shown in FIG. 5, the ESD device 1c comprises a gate electrode 20 provided over a region of the I/O P well 12. The gate electrode 20 could be a stack structure comprising, for example, a conductor such as a polysilicon layer, metal or metal silicide, and insulator such as a silicon nitride capping the conductor. It is understood that the gate electrode 20 could be any suitable gate structure commonly used in the I/O devices. A gate dielectric layer 22 could be provided between the gate electrode 20 and the I/O P well 12. The gate dielectric layer 22 could be formed by a gate dielectric layer for an I/O device. The gate dielectric layer 22 could be formed concurrently with the I/O devices and thus has a thicker thickness than that of the core devices. For example, the gate dielectric layer 22 could have a thickness of about 35-70 angstroms, while the core devices (not shown) could have a thickness of about 10-25 angstroms, based on a 65 nm technology node. A sidewall spacer 24a and a sidewall spacer 24b could be formed on two opposite sidewalls of the gate electrode 20. The sidewall spacers 24a and 24b could comprise dielectric materials such as silicon oxide, silicon nitride, silicon oxynitride or a combination thereof. It is to be understood that the sidewall spacers 24a and 24b could further comprise a liner such as an oxide liner in one embodiment.

On the left-hand side of the gate electrode 20, a source structure 30 is provided in the I/O P well 12. The source structure 30 could include a first NLDD region 14 that is disposed under the sidewall spacer 24a, a N+ source region 15 disposed next to the first LDD region 14, and a salicide layer 15a on the N+ source region 15. The first NLDD region 14 could be an I/O NLDD region formed by an LDD implantation process for an I/O device. On the right-hand side of the gate electrode 20, a drain structure 40 is provided in the I/O P well 12 and is opposite to the source structure 30. The drain structure 40 could include a second NLDD region 16 that is disposed under the sidewall spacer 24b, a N+ drain region 18 disposed next to the second LDD region 16, and a salicide layer 18a on the N+ drain region 18. The N+ drain region 18 could be coupled to an I/O pad. The salicide layer 18a, which could be cobalt salicide or nickel salicide for example, could be formed with an offset d away from the edge of the sidewall spacer 24b to prevent leakage.

According to this embodiment, the ESD device 1c has an asymmetric LDD configuration including the first LDD region 14 of the source structure 30 and the second LDD region 16 of the drain structure 40, wherein a doping concentration of the second LDD region 16 is substantially equal to a doping concentration of the first LDD region 14, and the junction of the second LDD region 16 is shallower than that of the first LDD region 14. For example, in accordance with one embodiment, the first NLDD region 14 could have a junction depth of about 300-1,000 angstroms. The second NLDD region 16 could have a junction depth of about 200-900 angstroms.

To have the asymmetric LDD configuration, in this embodiment, the ESD device 1 does not include an I/O NLDD or any extra ESD implant in its drain structure 40, but instead, incorporates the second NLDD 16 with shallower junction. By incorporating the second NLDD 16 with shallower junction and by eliminating the I/O NLDD from the drain structure 40, the junction breakdown voltage of the ESD device 1c can be reduced and better ESD performance can be obtained.

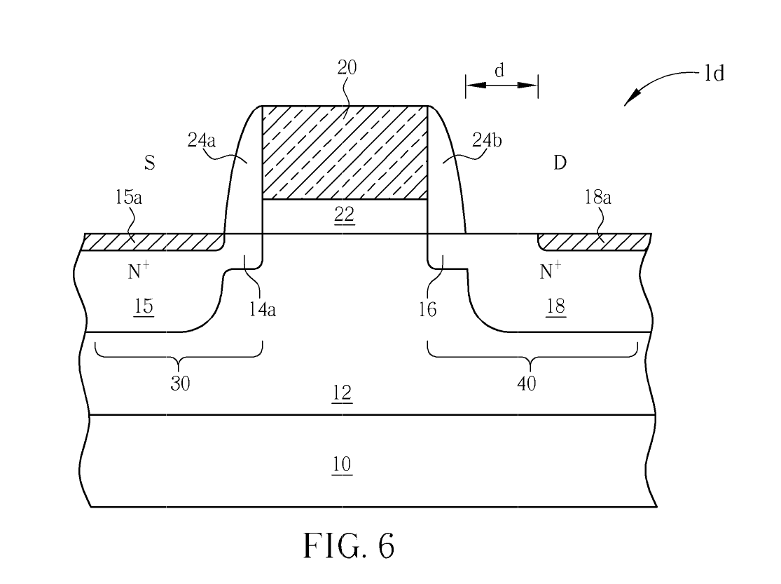

FIG. 6 shows a cross-sectional view of an ESD device 1d according to still another embodiment of this invention. According to another embodiment of this invention, the ESD device 1d includes the first LDD region 14 of the source structure 30 and the second LDD region 16 of the drain structure 40, wherein a doping concentration of the second LDD region 16 is greater than a doping concentration of the first LDD region 14, and the junction of the second LDD region 16 is substantially equal to that of the first LDD region 14. For example, in accordance with one embodiment, the first NLDD region 14 could be formed by implanting N type dopants, such as phosphorus and arsenic, with a dosage of, for example, about 2×10¹³−8×10¹³ atoms/cm², and the first NLDD region 14 could have a junction depth of about 300-1,000 angstroms. In accordance with one embodiment, the second NLDD 16 could be formed by implanting N type dopants, such as arsenic, with a dosage of, for example, about 5×10¹⁴−3×10¹⁵ atoms/cm², and the second NLDD region 16 could have a junction depth of about 300-1,000 angstroms.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An I/O electrostatic discharge (ESD) device, comprising:
a gate electrode over a substrate;
a gate dielectric layer between the gate electrode and the substrate;
a pair of sidewall spacers respectively disposed on two opposite sidewalls of the gate electrode;
a first lightly doped drain (LDD) region disposed under one of the sidewall spacers;
a source region disposed next to the first LDD region;
a second LDD region disposed under the other sidewall spacer; and
a drain region disposed next to the second LDD region;
wherein a junction of the second LDD region is shallower than that of the first LDD region.

2. The I/O ESD device according to claim 1 wherein a doping concentration of the second LDD region is substantially equal to a doping concentration of the first LDD region.

3. The I/O ESD device according to claim 1 wherein the drain region is coupled to an I/O pad.

4. The I/O ESD device according to claim 1 wherein the gate dielectric layer is formed by a gate dielectric layer for an I/O device.

5. The I/O ESD device according to claim 1 wherein the first LDD region has a junction depth of about 300-1,000 angstroms.

6. The I/O ESD device according to claim 1 wherein the second LDD region has a junction depth of about 200-900 angstroms.

7. The I/O ESD device according to claim 1 further comprising a source salicide layer on the source region.

8. The I/O ESD device according to claim 1 further comprising a drain salicide layer on the drain region with an offset away from an edge of the sidewall spacer to prevent leakage.

9. The I/O ESD device according to claim 1 wherein the first LDD region, the second LDD region, the source region and the drain region are all disposed in an I/O P well.

10. An I/O electrostatic discharge (ESD) device, comprising:
a gate electrode over a substrate;
a gate dielectric layer between the gate electrode and the substrate;
a pair of sidewall spacers respectively disposed on two opposite sidewalls of the gate electrode;
a first lightly doped drain (LDD) region disposed under one of the sidewall spacers;
a source region disposed next to the first LDD region;
a second LDD region disposed under the other sidewall spacer; and
a drain region disposed next to the second LDD region;
wherein a junction of the second LDD region is substantially equal to that of the first LDD region, and a doping concentration of the second LDD region is greater than a doping concentration of the first LDD region.

11. The I/O ESD device according to claim 10 wherein the drain region is coupled to an I/O pad.

12. The I/O ESD device according to claim 10 wherein the gate dielectric layer is formed by a gate dielectric layer for an I/O device.

13. The I/O ESD device according to claim 10 wherein the first LDD region has a junction depth of about 300-1,000 angstroms.

14. The I/O ESD device according to claim 10 wherein the second LDD region has a junction depth of about 200-900 angstroms.

15. The I/O ESD device according to claim 10 further comprising a source salicide layer on the source region.

16. The I/O ESD device according to claim 10 further comprising a drain salicide layer on the drain region with an offset away from an edge of the sidewall spacer to prevent leakage.

17. The I/O ESD device according to claim 10 wherein the first LDD region, the second LDD region, the source region and the drain region are all disposed in an I/O P well.
